(19) United States
(12) Patent Application Publication
(10) Pub. No.: US 2025/0167066 A1
(43) Pub. Date: May 22, 2025

(54) POWER MODULES

(71) Applicants: Hyundai Motor Company, Seoul (KR); Kia Corporation, Seoul (KR)

(72) Inventors: Nam Sik KONG, Hwaseong-Si (KR); Sung Taek HWANG, Seoul (KR); Jun Hee PARK, Hwaseong-Si (KR); Se Yoon JEONG, Hwaseong-Si (KR)

(73) Assignees: Hyundai Motor Company, Seoul (KR); Kia Corporation, Seoul (KR)

(21) Appl. No.: 18/798,770

(22) Filed: Aug. 8, 2024

(30) Foreign Application Priority Data
Nov. 21, 2023 (KR) 10-2023-0162481

(51) Int. Cl. H01L 23/367; H01L 21/48; H01L 23/00; H01L 23/46; H01L 23/495

(52) U.S. Cl. CPC H01L 23/3672; H01L 21/4842; H01L 23/46; H01L 23/49568; H01L 24/32; H01L 2224/32245

(57) ABSTRACT

A power module includes an insulating layer, a first metal layer disposed on a first surface of the insulating layer, and including a first intaglio pattern, and a second metal layer disposed on a second surface of the insulating layer, and including a second intaglio pattern. The second intaglio pattern is formed so that the second metal layer has a volume corresponding to a volume of the first metal layer.

### CROSS REFERENCE TO RELATED APPLICATIONS

The present application claims priority to Korean Patent Application No. 10-2023-0162481, filed Nov. 21, 2023, the entire contents of which is incorporated herein for all purposes by this reference.

### BACKGROUND OF THE PRESENT DISCLOSURE

### Field of the Present Disclosure

The present disclosure relates to a power module having improved durability in balancing volumes of metal layers.

### Description of Related Art

In recent, as interest in the environment has increased, the number of eco-friendly vehicles equipped with electric motors as a power source is increasing. The eco-friendly vehicles are also called electrified vehicles, and representative examples thereof include electric vehicles (EV) and hybrid electric vehicles (HEV).

The electric vehicle is equipped with an inverter for converting DC power into AC power when driving a motor, and the inverter is usually made of one or a plurality of power modules equipped with a semiconductor chip performing switching function.

In the operation process of the power module as described above, heat generated by the semiconductor chip provided in the power module is accompanied, and if the high temperature condition due to heat generation is not resolved, the operating performance of the power module may deteriorate.

Therefore, various methods are applied to improve the operating performance while resolving heat generated by the power module, and among them, a method of connecting a cooling channel in which a cooling fluid flows to an outside part of the power module may be referred as an example.

In the instant case, a heat sink for resolving the heat may be provided in the power module, and the heat sink may be separately attached to an outside part of the power module, or may be integrally provided at a substrate of the power module.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a heat sink integrated power module having low processing cost and improved durability.

The problem of the present disclosure is not limited to the above mention, and other problems not mentioned will be clearly understood by those skilled in the art from the description below.

To achieve the above-mentioned problem, according to an exemplary embodiment of the present disclosure, there is provided a power module including: an insulating layer; a first metal layer disposed on a first surface of the insulating layer, and including a first intaglio pattern; and a second metal layer disposed on a second surface of the insulating layer, and including a second intaglio pattern, wherein the second intaglio pattern may be formed so that the second metal layer has a volume corresponding to a volume of the first metal layer.

For example, the first intaglio pattern and the second intaglio pattern may be formed so that the first metal layer and the second metal layer have different planar shapes from each other.

For example, the first intaglio pattern and the second intaglio pattern may be formed so that the first metal layer and the second metal layer have different cross-sectional shapes from each other.

For example, the first intaglio pattern may form an electrical path on the first metal layer.

For example, the first intaglio pattern may be formed by penetrating a portion of the first metal layer to expose the insulating layer toward the penetrated portion of the first metal layer.

For example, the power module may include a semiconductor chip disposed on a first peripheral portion that relatively protrudes outside a portion with the first intaglio pattern on the first metal layer.

For example, the second intaglio pattern may be formed on the second metal layer to prevent the insulating layer from being exposed in a direction toward the second metal layer.

For example, the second intaglio pattern may be formed to form a second peripheral portion into a pin shape, the second peripheral portion relatively protruding outside a portion of the second metal layer wherein the intaglio is formed.

For example, the power module may include a cooling channel in which a cooling fluid in contact with the second peripheral portion flows.

For example, the first intaglio pattern may be formed by penetrating a portion of the first metal layer to expose the insulating layer in a direction toward the first metal layer through the penetrated portion, and the second intaglio pattern may be formed on the second metal layer to prevent the insulating layer from being exposed in a direction toward the second metal layer.

For example, the first intaglio pattern may be formed to gradually reduce a thickness of a cross section of the first metal layer in a direction toward a center portion of the intaglio.

For example, the second intaglio pattern may be formed to gradually reduce a thickness of a cross section of the second metal layer in a direction toward a center portion of the intaglio.

For example, the first intaglio pattern and the second intaglio pattern may be formed by removing a portion of the first metal layer and a portion of the second metal layer by etching.

For example, at least one of the first and second intaglio patterns may be formed by wet-etching using chemical reaction.

For example, the first intaglio pattern and the second intaglio pattern may be formed by etching the first metal layer and the second metal layer after the first metal layer and the second metal layer are respectively bonded to both the surfaces of the insulating layer.

According to the various embodiments of the present disclosure described above, the volumes of the metal layers on the opposite surfaces of the insulating layer are balanced to each other, so that it is possible to alleviate a deterioration in durability such as bending of the substrate due to asymmetry in volume, crack occurrences in the semiconductor chip, etc.

Moreover, the present disclosure can provide the structure in which the heat sink is integrated, with the simple process and low processing cost.

The effect of the present disclosure is not limited to the above mention, and other effects not mentioned will be clearly understood by those skilled in the art from the description below.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a cross-sectional view showing a power module according to an exemplary embodiment of the present disclosure.

FIG. 2 is a plane view showing a portion of a first metal layer of the power module according to the exemplary embodiment of the present disclosure.

FIG. 3 is a plane view showing a portion of a second metal layer of the power module according to the exemplary embodiment of the present disclosure.

FIG. 4 is a view showing a manufacturing process of the power module according to the exemplary embodiment of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

In the following description, the structural or functional description specified to an exemplary embodiment according to the concept of the present disclosure is directed to describe the exemplary embodiments of the present disclosure, so it should be understood that the present disclosure may be variously embodied, without being limited to the exemplary embodiments of the present disclosure.

Embodiments described herein may be changed in various ways and various shapes, so specific embodiments are shown in the drawings and will be described in detail in the present specification. However, it should be understood that the exemplary embodiments according to the concept of the present disclosure are not limited to the exemplary embodiments which will be described hereinbelow with reference to the accompanying drawings, but all of modifications, equivalents, and substitutions are included in the scope and spirit of the present disclosure.

Unless otherwise defined, all terms including technical and scientific terms used herein have the same meaning as commonly understood by those skilled in the art to which the present disclosure belongs. It may be understood that the terms defined by the dictionary are identical with the meanings within the context of the related art, and they should not be ideally or excessively formally defined unless the context clearly dictates otherwise.

Hereafter, an exemplary embodiment of the present disclosure will be described in detail with reference to the accompanying drawings and the same or similar components are provided the same reference numerals regardless of the numbers of figures and are not repeatedly described.

In the following description, if it is decided that the detailed description of known technologies related to the present disclosure makes the subject matter of the exemplary embodiment described herein unclear, the detailed description is omitted. Furthermore, the accompanying drawings are provided only for easy understanding of the exemplary embodiment included in the specification, and the technical spirit included in the specification is not limited by the accompanying drawings, and all changes, equivalents, and replacements should be understood as being included in the spirit and scope of the present disclosure.

Terms including ordinal numbers such as “first”, “second”, etc. may be used to describe various components, but the components are not to be construed as being limited to the terms. The terms are used only to distinguish one component from another component.

It is to be understood that when one element is referred to as being “connected to” or “coupled to” another element, it may be directly connected to or directly coupled to another element or be connected to or coupled to another element, including the other element intervening therebetween. On the other hand, it should be understood that when one element is referred to as being “directly connected to” or “directly coupled to” another element, it may be connected to or coupled to another element without the other element intervening therebetween.

Singular forms are intended to include plural forms unless the context clearly indicates otherwise.

It will be further understood that the terms “comprise” or “have” used in the present specification, specify the presence of stated features, steps, operations, components, parts, or a combination thereof, but do not preclude the presence or addition of one or more other features, numerals, steps, operations, components, parts, or a combination thereof.

A power module according to the exemplary embodiment of the present disclosure is configured to form intaglio patterns on metal layers arranged at opposite surfaces of an insulating layer to achieve balance of volumes thereof, and thus it is provided to alleviate a deterioration in durability of the power module due to bending of a substrate, a crack of a semiconductor chip, etc.

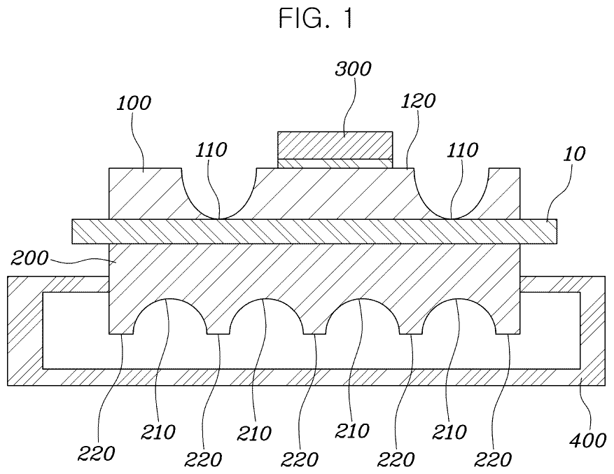

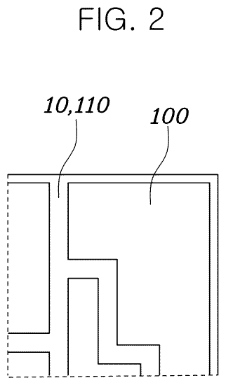

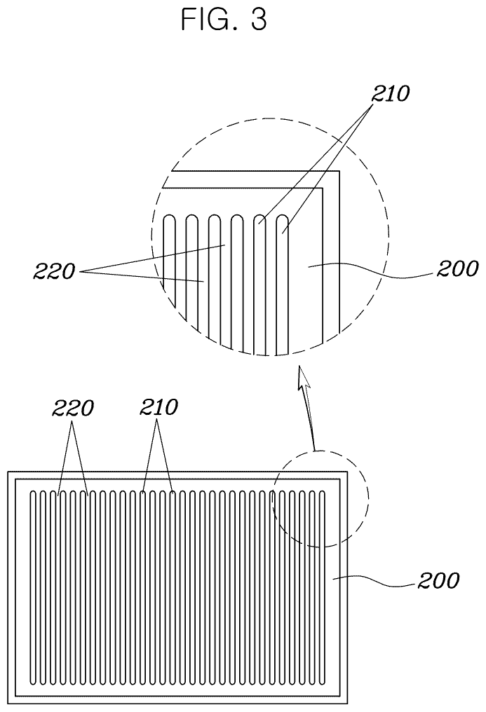

Hereinbelow, configuration of the power module according to the exemplary embodiment of the present disclosure will be described with reference to FIG. 1, FIG. 2, and FIG. 3.

FIG. 1 is a cross-sectional view showing a power module according to an exemplary embodiment of the present disclosure. FIG. 2 is a plane view showing a portion of a first metal layer of the power module according to the exemplary embodiment of the present disclosure. FIG. 3 is a plane view showing a portion of a second metal layer of the power module according to the exemplary embodiment of the present disclosure.

Referring to FIG. 1, FIG. 2, and FIG. 3, the power module according to the exemplary embodiment of the present disclosure may include an insulating layer 10, a first metal layer 100, a second metal layer 200, a semiconductor chip 300, and a cooling channel 400. However, FIG. 1 mainly shows components, which relate to the description for the exemplary embodiment of the present disclosure, and the power module may be actually implemented with more of fewer components than the shown components. Hereinbelow, each component will be described in detail.

First, the insulating layer 10 may be made of an insulator, for example. ceramic, etc., and may include a plate shape.

The first metal layer 100 and the second metal layer 200 may be respectively provided on a first surface and a second surface of the insulating layer 10, may insulate from each other through the insulating layer 10, for example, and may be made of copper.

The first metal layer 100 and the second metal layer 200 may respectively include a first intaglio pattern 110 and a second intaglio pattern 210. The second intaglio pattern may be formed so that the second metal layer 200 has a volume corresponding to a volume of the first metal layer 100.

At the present point, the first intaglio pattern 110 and the second intaglio pattern 210 may be formed on the first metal layer 100 and the second metal layer 200 and may have reduced thicknesses in comparison to surrounding portions thereof.

Furthermore, for the volume of the first metal layer 100 and the volume of the second metal layer 200 to correspond to each other, the first metal layer 100 and the second metal layer 200 may have the same volumes, and although the volumes of the first and second metal layer 100 and 200 are not exactly the same, they may be at a similar volume.

For example, the volume of the first metal layer 100 and the volume of the second metal layer 200 may be formed to correspond to each other in a ratio of 4 to 6:6 to 4.

The first intaglio pattern 110 and the second intaglio pattern 210 may be formed so that the first metal layer 100 and the second metal layer 200 have different planar shapes from each other, or so that the first metal layer 100 and the second metal layer 200 have different cross-sectional shapes from each other. For example, the first metal layer 100 may have a planar shape as shown in FIG. 2, and the second metal layer 200 may have a planar shape as shown in FIG. 3, and may have a cross-sectional shape as shown in FIG. 1.

However, when the first metal layer 100 and the second metal layer 200 have different planar shapes or different cross-sectional shapes, the first intaglio pattern 110 and the second intaglio pattern 210 may be formed so that the first metal layer 100 and the second metal layer 200 have the volumes corresponding to each other. The second intaglio pattern 210 may be formed so that the second metal layer 200 has the volume corresponding to the volume of the first metal layer 100, on the basis of the volume of the first metal layer 100 formed by the first intaglio pattern 110.

Meanwhile, the first intaglio pattern 110 may form an electrical path on the first metal layer 100. In other words, the first intaglio pattern 110 may serve as a circuit pattern that forms the electrical path inside the power module.

In the instant case, the first intaglio pattern 110 may be formed by penetrating through the first metal layer 100 so that the insulating layer 10 is exposed toward the first metal layer 100. In other words, the first intaglio pattern 110 may be formed so that a cross-sectional thickness of the first metal layer 100 is completely reduced to expose the insulating layer 10, which is in direct contact with the first metal layer 100, through the first intaglio pattern 110.

Furthermore, the semiconductor chip 300 is disposed on a first peripheral portion 120 to be electrically connected to the first metal layer 100, and the first peripheral portion 120 relatively protrudes outside a portion of the first metal layer 100, on which the first intaglio pattern 110 is formed. In the instant case, the semiconductor chip 300 may be bonded to the first peripheral portion 120, and for example, bonding may be performed by soldering, sintering, or the like.

Meanwhile, the second intaglio pattern 210 may be formed on the second metal layer 200 to prevent the insulating layer 10 from being exposed toward the second metal layer 200. In other words, unlike the first intaglio pattern 110, the second intaglio pattern 210 may be formed without completely penetrating through a surface of the second metal layer 200. Instead, the second intaglio pattern 210 may be formed by recessing a surface of the second metal layer 200 so that the recessed surface of the second metal layer 200 is spaced from a top surface of the second metal layer 200.

In the instant case, the second intaglio pattern 210 may be formed to form a second peripheral portion 220 into a pin shape, and the second peripheral portion 220 relatively protrudes outside a portion of the second metal layer wherein the intaglio is formed 200. However, the second peripheral portion 220 is not limited to the above-described shape, and may include a form of a micro channel, etc.

In other words, the second peripheral portion 220 may have an appropriate shape to serve as a heat sink, and the second intaglio pattern 210 may allow the heat sink to be integrally formed with the second metal layer 200. In the instant case, an area where the second metal layer 200 is exposed outwards is increased through the second intaglio pattern 210, so that heat dissipation performance may be improved.

Moreover, the power module according to the exemplary embodiment of the present disclosure may include the cooling channel 400 in which a cooling fluid in contact with the second peripheral portion 220 flows. In the instant case, the cooling performance is improved compared to when the cooling channel 400 is not provided, and the cooling efficiency through the cooling channel 400 may be improved with increasing a contact area between the cooling fluid and the second metal layer 200.

Meanwhile, the characteristics due to the first intaglio pattern 110 and the second intaglio pattern 210 that are described above may be applied simultaneously in the exemplary embodiment of the present disclosure. In other words, the first intaglio pattern 110 is formed by penetrating through the first metal layer 100 so that the insulating layer 10 is exposed outwards in the direction toward the first metal layer 100, and the second intaglio pattern 210 may be formed on the second metal layer 200 so that the insulating layer 10 is not exposed outwards in the direction toward the second metal layer 200.

Therefore, the first metal layer 100 may include the circuit pattern by the first intaglio pattern 110, and the second metal layer 200 may have the heat sink by the second intaglio pattern 210. In the instant case, since the first metal layer 100 and the second metal layer 200 are also formed so that the volumes thereof correspond to each other, it is possible to alleviate a deterioration in durability occurring while the substrate may be bent due to asymmetry in volume or a crack occurs in the semiconductor chip 300.

As shown in FIG. 1, the first intaglio pattern 110 is formed to gradually reduce a thickness of a cross section of the first metal layer 100 in a direction toward a center portion of an intaglio portion thereof so that the first intaglio pattern 110 has an oval shape a parabolic shape, or a semi-circle shape in the cross section, and the second intaglio pattern 210 may be also formed like the shape of the first intaglio pattern 110.

When the first metal layer 100 and the second metal layer 200 are formed so that the thickness of the cross section of each of the first metal layer 100 and the second metal layer 200 is gradually reduced, in comparison when the thickness of the section is uniformly reduced at the same time, thermal stress applied to an end portion of each of the first intaglio pattern 110 and the second intaglio pattern 210, i.e., to each of the first peripheral portion 120 and the second peripheral portion 220, may be reduced and therefore a deterioration in durability of the power module may be efficiently alleviated.

However, both the first intaglio pattern 110 and the second intaglio pattern 210 or at least one of the first and second intaglio patterns 110 and 210 may have a shape which is bent perpendicular from each of the first peripheral portion 120 and the second peripheral portion 220 on the cross section thereof as the thickness of the first metal layer 100 or the second metal layer 200 is uniformly reduced.

Meanwhile, the first intaglio pattern 110 and the second intaglio pattern 210 may be formed by etching a portion of the first metal layer 100 and a portion of the second metal layer 200 by etching. In the instant case, a processing cost may be reduced compared to when the circuit pattern or the heat sink is formed by a machine processing.

As an etching method, dry etching using reaction gases, etc. may be utilized, and wet etching using chemical reaction may be utilized. When the first intaglio pattern 110 and the second intaglio pattern 210 are formed by wet etching, the cross section of the first intaglio pattern 110 and the second intaglio pattern 210 may have an oval shape as described above with reference to FIG. 1, and a deterioration in durability due to thermal stress may be efficiently alleviated.

Meanwhile, the first intaglio pattern 110 and the second intaglio pattern 210 may be formed by bonding the first metal layer 100 and the second metal layer 200 on the opposite surfaces of the insulating layer 10 and then etching the first metal layer 100 and the second metal layer 200.

In the instant case, compared to the method in which the circuit pattern, the heat sink, etc. are formed on the first metal layer 100 and the second metal layer 200 and then the first metal layer 100 and the second metal layer 200 are bonded, crack occurrences on the insulating layer 10 due to asymmetry of the opposite surfaces of the insulating layer 10 in processing, occurrence of alignment failure of the first metal layer 100 and the second metal layer 200, etc. may be alleviated, thereby reducing processing difficulty and cost.

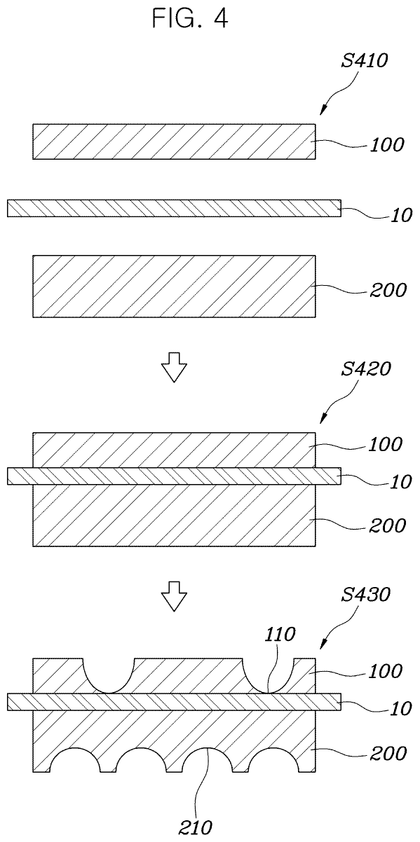

Hereinbelow, a manufacturing process of the power module according to an exemplary embodiment will be described with reference to FIG. 4.

FIG. 4 is a view showing a manufacturing process of the power module according to the exemplary embodiment of the present disclosure.

Referring to FIG. 4, first, the insulating layer 10, the first metal layer 100 and the second metal layer 200 are respectively provided, at S410, and then bonding the first metal layer 100 and the second metal layer 200 on the opposite surfaces of the insulating layer 10 is performed prior to processing of the first metal layer 100 and the second metal layer 200, at S420. In the instant case, the bonding of the first metal layer 100 and the second metal layer 200 at S420 may be performed in a condition of high temperature and high pressure.

Only after the first metal layer 100 and the second metal layer 200 are bonded to the insulating layer 10, the first metal layer 100 and the second metal layer 200 are processed, at S430. In the instant case, processing of the first metal layer 100 and the second metal layer 200 may be performed by etching, by wet etching. The above process may be formed so that the circuit pattern is formed on the first metal layer 100 and the heat sink is formed on the second metal layer 200, and as a result of the processing, the volume of the first metal layer 100 and the volume of the second metal layer 200 correspond to each other.

According to the various embodiments of the present disclosure described above, the volumes of the metal layers on the opposite surfaces of the insulating layer are balanced to each other, so that it is possible to alleviate a deterioration in durability such as bending of the substrate due to asymmetry in volume, crack occurrences in the semiconductor chip, etc.

Moreover, the present disclosure can provide the structure in which the heat sink is integrated, with the simple process and low processing cost.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In the present specification, unless stated otherwise, a singular expression includes a plural expression unless the context clearly indicates otherwise.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A power module comprising:
an insulating layer;
a first metal layer disposed on a first surface of the insulating layer, and including a first intaglio pattern; and
a second metal layer disposed on a second surface of the insulating layer, and including a second intaglio pattern,
wherein the second intaglio pattern is formed so that the second metal layer includes a volume corresponding to a volume of the first metal layer.

2. The power module of claim 1, wherein the first intaglio pattern and the second intaglio pattern are formed so that the first metal layer and the second metal layer have different planar shapes from each other.

3. The power module of claim 1, wherein the first intaglio pattern and the second intaglio pattern are formed so that the first metal layer and the second metal layer have different cross-sectional shapes from each other.

4. The power module of claim 1, wherein the first intaglio pattern forms an electrical path on the first metal layer.

5. The power module of claim 4, wherein the first intaglio pattern is formed by penetrating a portion of the first metal layer to expose the insulating layer toward the penetrated portion of the first metal layer.

6. The power module of claim 5, further including:
a semiconductor chip disposed on a first peripheral portion that relatively protrudes outside a portion of the first metal layer where the first intaglio pattern is formed.

7. The power module of claim 1, wherein the second intaglio pattern is formed on the second metal layer to prevent the insulating layer from being exposed in a direction toward the second metal layer.

8. The power module of claim 7, wherein the second intaglio pattern is formed by recessing a surface of the second metal layer so that the recessed surface of the second metal layer is spaced from a top surface of the second metal layer.

9. The power module of claim 7, wherein the second intaglio pattern is formed to include a second peripheral portion shaped of a pin, the second peripheral portion relatively protruding outside a portion of the second metal layer wherein an intaglio of the second intaglio pattern is formed.

10. The power module of claim 9, further including:
a cooling channel into which the second peripheral portion is positioned and in which a cooling fluid in contact with the second peripheral portion flows.

11. The power module of claim 1,
wherein the first intaglio pattern is formed by penetrating a portion of the first metal layer to expose the insulating layer in a direction toward the first metal layer through the penetrated portion, and
wherein the second intaglio pattern is formed on the second metal layer to prevent the insulating layer from being exposed in a direction toward the second metal layer.

12. The power module of claim 11, wherein the second intaglio pattern is formed by recessing a surface of the second metal layer so that the recessed surface of the second metal layer is spaced from a top surface of the second metal layer.

13. The power module of claim 1, wherein the first intaglio pattern is formed to reduce a thickness of a cross section of the first metal layer in a direction toward a center portion of an intaglio in the first intaglio pattern.

14. The power module of claim 1, wherein the second intaglio pattern is formed to reduce a thickness of a cross section of the second metal layer in a direction toward a center portion of an intaglio in the second intaglio pattern.

15. The power module of claim 1, wherein the first intaglio pattern and the second intaglio pattern are formed by removing a portion of the first metal layer and a portion of the second metal layer by etching.

16. The power module of claim 15, wherein at least one of the first and second intaglio patterns is formed by wet-etching using chemical reaction.

17. The power module of claim 15, wherein the first intaglio pattern and the second intaglio pattern are formed by etching the first metal layer and the second metal layer after the first metal layer and the second metal layer are respectively bonded to the first and second surfaces of the insulating layer.
